(19) United States
(12) Patent Application Publication
(10) Pub. No.: US 2025/0327859 A1
(43) Pub. Date: Oct. 23, 2025

(54) SYSTEMS AND METHODS FOR AUTOMATED ANALYSIS OF VOLTAGE CONTRAST DEFECTS IN INTEGRATED CIRCUIT INSPECTION

(71) Applicant: Taiwan Semiconductor Manufacturing Company, Ltd., Hsinchu (TW)

(72) Inventors: Chien-Huei Chen, Kaohsiung (TW); Wei-Chun Wang, New Taipei (TW); Yu-Hsiang Cheng, New Taipei (TW); Wei-Hsiang Huang, Tainan (TW); Chun-Yi Chen, Taichung (TW); Kuan-Ying Huang, Hsinchu (TW); Zong-Zhe Wu, Hsinchu (TW); Wei-Hsun Lin, Hsinchu (TW); Kuang-Shing Chen, Hsinchu (TW); Hung-Ming Chen, New Taipei (TW); Hsien-Tsung Chiang, Taichung (TW); Xiaomeng Chen, Baoshan (TW)

(21) Appl. No.: 18/640,939

(22) Filed: Apr. 19, 2024

(51) Int. Cl. G01R 31/307

(52) U.S. Cl. CPC G01R 31/307

(57) ABSTRACT

Analysis of an integrated circuit (IC) includes acquiring a review scanning electron microscope (RSEM) image of the IC, and acquiring a voltage contrast electron beam image of the IC. A layout image is rendered from a layout file descriptive of a layout of the IC. A transform between spatial coordinates of the RSEM image of the IC and spatial coordinates of the voltage contrast electron beam image of the IC is determined using the layout image. A voltage contrast (VC) defect or other VC targeted pattern is identified in the voltage contrast electron beam image of the IC, and at least one region of interest (ROI) is located in the RSEM image of the IC associated with the VC defect using the spatial transform. The at least one ROI in the RSEM image of the IC is analyzed to produce information for the VC defect or other VC targeted pattern.

### BACKGROUND

The following relates to the semiconductor fabrication arts, semiconductor quality control, semiconductor defect analysis, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a wafer defect assessment system employing a scanning electron microscope (SEM) configured to acquire review scanning electron microscope (RSEM) images and a voltage contrast electron beam inspection or imaging (VC-EBI) microscope.

FIG. 2 diagrammatically illustrates a method of generating a transform between spatial coordinates of an RSEM image of an integrated circuit (IC) and spatial coordinates of a voltage contrast electron beam image of the IC.

FIG. 3 diagrammatically illustrates a defect analysis method for analyzing a VC defect identified in a voltage contrast electron beam image of an IC using an RSEM image of the IC and a transform generated by the method of FIG. 2.

FIG. 4 diagrammatically illustrates a nonlimiting illustrative example of an implementation of the VC defects identifier of the wafer defect assessment system of FIG. 1.

FIG. 5 diagrammatically illustrates a nonlimiting illustrative example of an implementation of a customized algorithm for detection of a VC defect due to a metal gate extrusion.

FIG. 6 diagrammatically illustrates a nonlimiting illustrative example of an RSEM image depicting a portion of an IC with a VC defect, and regions of interest for the VC defect.

FIG. 7 diagrammatically illustrates a high energy (HE) RSEM image and a low energy (LE) RSEM image, and diagrammatically indicates detection of a root cause defect in the HE RSEM image corresponding to a defect in a drain epitaxy layer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

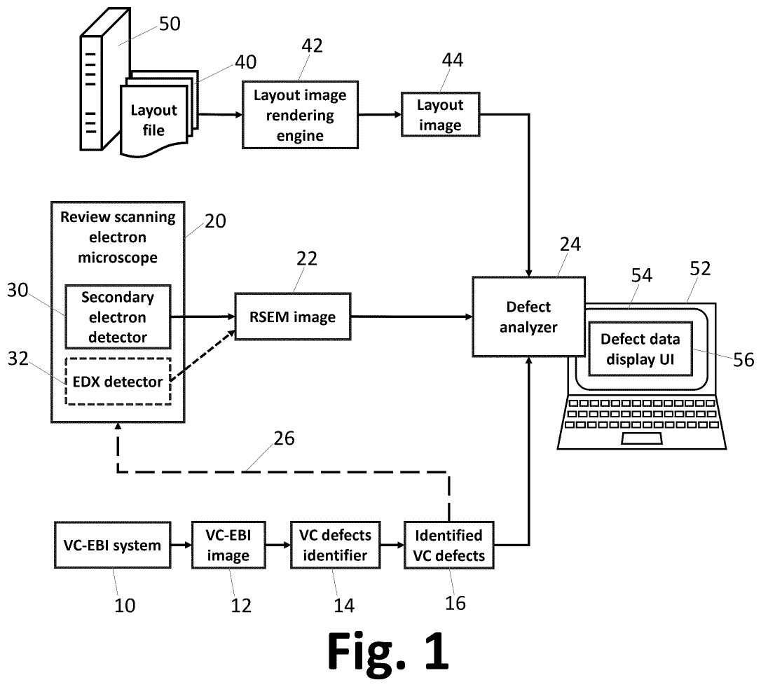

With reference to FIG. 1, a voltage contrast electron beam inspection or imaging (VC-EBI) system 10 is provided. The VC-EBI system 10 may include a scanning electron microscope (SEM) or similar instrument with an evacuated housing, an electron beam source directing an accelerated electron beam onto an integrated circuit (IC) formed on a semiconductor wafer (or otherwise disposed) which is mounted on a stage, with the stage being connected to a voltage source in order to apply a stage bias to the IC (details not illustrated), and a secondary electron detector for measuring secondary electrons emitted from the IC in response to the applied electron beam. A voltage contrast electron beam image (i.e., VC-EBI image) 12 is acquired using the VC-EBI system 10, by moving the sample stage (or, additionally or alternatively, steering the electron beam) to scan the IC two-dimensionally and acquire secondary electron signal as a function of scan location. VC-EBI imaging is a fast and effective method for identifying voltage contrast (VC) defects in an IC (or, more generally VC targeted patterns in an IC, which may be defects or other features of interest of an IC which exhibit detectable voltage contrast) due to electrical shorts or electrical opens in the IC. VC defects can lead to a reduction in yield. During the VC-EBI imaging, a stage bias is applied to the stage holding the semiconductor wafer (or other substrate) on or in which the IC is disposed, and a landing energy (LE) of the impinging electron beam is the accelerating voltage of the electron beam minus the stage bias. Depending on the landing energy, the SE yield may be greater than unity (positive mode VC-EBI, meaning that on average each electron of the electron beam results in more than one secondary electron being emitted from the wafer surface), less than unity (negative mode VC-EBI), or about equal to unity. In some nonlimiting illustrative examples, the voltage contrast electron beam image 12 is acquired with landing energy of about equal to unity (LE≈1) to achieve a charge neutral condition which can enhance sensitivity to defects. However, acquisition of the voltage contrast electron beam image 12 using other settings (e.g., positive mode or negative mode) is also contemplated. VC-EBI imaging advantageously can be performed at an early stage of middle end-of-line (MEOL) or back end-of-line (BEOL) processing, such as after initial (e.g., MO) metallization has formed metal gates (MG) and metallization contacts to source and drain regions (MD), and optionally further after formation of initial electrical interconnects.

VC-EBI imaging provides voltage contrast for various types of defects, such as defects related to or causing various types of electrical shunting, shorting, or open-circuit connections in an IC. For example, if the voltage contrast electron beam image is taken LE≈1, then a bright VC defect (i.e., enhanced electron yield at the defect) may correspond to an electrical short, while a dark VC defect (i.e., reduced electron yield at the defect) may correspond to an electrical open. Using a VC defect identifier 14, VC defects 16 are identified as, for example, regions of bright or dark contrast in the voltage contrast electron beam image 12.

However, the observed bright or dark contrast of the VC defect provides limited information about the root cause defect that produces the VC defect observed in the voltage contrast electron beam image 12, and it can be difficult or impossible to determine the root cause of a VC defect from the voltage contrast electron beam image alone. To guide process improvement, it is desirable to determine the exact type of defect and the layer at which the defect occurs. For example, an electrical short between MG (metal gate) and MD (metal connecting to drain or source) may be caused by various types of physical defects, such as metal gate extrusion or epitaxial damage at a certain layer. In addition, VC noise induced by local charging can be erroneously detected as false VC defects. For some process layers, the VC noise may overwhelm the true VC defects. Therefore, it is also desirable to distinguish VC noise from true VC defects as part of defect classification analysis.

With continuing reference to FIG. 1, in embodiments disclosed herein the VC-EBI imaging performed using the VC-EBI system 10 is advantageously combined with a review scanning electron microscope (RSEM) 20 that acquires an RSEM image 22 which is analyzed by a defect analyzer 24 to provide defect information about the VC defect (or, more generally, to provide information about the VC targeted pattern). The RSEM image 22 is a scanning electron microscope image acquired using the RSEM 20 which is a scanning electron microscope operated with imaging parameters that are effective for enabling analysis of the RSEM image 22 to provide defect information sufficient to better understand the source of a VC defect. In some embodiments, the defect analysis performed by the defect analyzer 24 is advantageously automated, and is effective to enable the defect information to include a determination of a root cause defect that caused the VC defect observed in the voltage contrast electron beam image 12. To enable defect analysis, the RSEM image 22 is of higher spatial resolution than the voltage contrast electron beam image 12. Hence, the defect analysis performed by the defect analyzer 24 of the RSEM image 22 can localize the root cause of the VC defect (or other VC targeted pattern) with higher spatial resolution. This can, for example, enable the root cause defect to be spatially localized to a specific location in a transistor or other IC component.

Due to the high resolution of the RSEM image 22, acquisition can be slow. Accordingly, in some inspection workflow embodiments, the voltage contrast electron beam image 12 is acquired first, the VC targeted patterns (e.g., VC defects in the illustrative embodiments) 16 are identified by the VC defect (or, more generally, VC targeted pattern) identifier 14, and RSEM images 22 are then acquired in the vicinity of some or all of the identified VC defects 16. The use of the identified VC defects 16 to guide the RSEM imaging is diagrammatically indicated in FIG. 1 by an arrow 26 indicating input of the VC defects 16 (or their locations in the voltage contrast electron beam image 12) to the RSEM 20. (The arrow 26 is shown by a dashed line in FIG. 1 to indicate this is an optional aspect. In other approaches, the RSEM 20 acquires the RSEM image 22 for the entire area of the IC under inspection, in which case such VC defect location-based RSEM imaging is suitably not employed.) This optional approach can improve the inspection workflow efficiency, especially if the number of identified VC defects 16 is relatively low (or if only a subset of the identified VC defects 16 are further characterized by RSEM) since the RSEM images 22 can be acquired only in the vicinity of the VC defects, rather than acquiring an RSEM image that encompasses the entire IC (or array of ICs on a semiconductor wafer). Hence, it is noted that while an RSEM image 22 is generally referred to herein, the RSEM image 22 may include a plurality of RSEM images, with different RSEM images acquired for different regions of the IC. The RSEM image 22 may encompass the entire IC undergoing inspection, or an entire array of ICs fabricated on a semiconductor wafer undergoing inspection, or may encompass only a portion of the IC encompassing the VC defect.

Additionally or alternatively, the RSEM image 22 may include a plurality of RSEM images acquired with different imaging parameters. As a nonlimiting illustrative example, the RSEM image 22 may include two (or more) RSEM images acquired with different accelerating voltages for the electron beam used in the RSEM image acquisition. As a specific nonlimiting illustrative example, a low energy (LE) RSEM image may be acquired using an electron beam with a first accelerating voltage, and a high energy (HE) RSEM image may be acquired using an electron beam with a second accelerating voltage that is higher than the first accelerating voltage. The higher accelerating voltage of the HE RSEM image means that it probes deeper into the IC than the LE RSEM image; accordingly, if a defect is detected in the HE RSEM image but not in the LE RSEM image (or, if the defect is detected more strongly in the HE RSEM image than in the LE RSEM image) then it may be concluded that the root cause defect is in a buried layer that is (more strongly) probed by the HE RSEM image than by the LE RSEM image. Conversely, if a defect is detected in the LE RSEM image but not in the HE RSEM image (or, if the defect is detected more strongly in the LE RSEM image than in the HE RSEM image) then it may be concluded that the root cause defect is in layer at or closer to the surface that is (more strongly) probed by the LE RSEM image than by the HE RSEM image.

As another nonlimiting illustrative example of the RSEM image 22 comprising different RSEM images acquired with different imaging parameters, the RSEM image 22 may include: (1) at least one RSEM image acquired using a secondary electron (SE) detector 30, and (2) at least one energy-dispersive X-ray (EDX) image acquired using an EDX spectrometer 32, in a technique known as energy-dispersive X-ray (EDX) imaging. The optional use of EDX imaging is diagrammatically indicated in FIG. 1 by showing the optional EDX spectrometer 32 using a dashed line. Moreover, these are merely nonlimiting illustrative examples, and the RSEM image 22 may be acquired using other types of SEM detectors, such as a backscattered electron (BSE) detector (not shown).

The defect analysis performed on the RSEM image 22 by the defect analyzer 24 can provide defect information about the VC defect identified by the VC defect identifier 14, potentially including identifying the root cause of the VC defect. However, the analysis of the RSEM image to identify the root cause of the VC defect is challenging for various reasons. The lower resolution voltage contrast electron beam image does not enable for precise mapping the VC defect to coordinates of the higher resolution RSEM image 22. Furthermore, the root cause defect that causes the identified VC defect may be located some distance away from the VC defect. For example, a short between a metal gate (MG) and a metal drain contact (MD) may cause a VC defect that is observed some distance away from the root cause short.

Still further, the root cause defect may be embedded in a buried layer of the IC and may not be very visible in the RSEM image 22. The IC may have multiple process layers (for example, one or more process layers corresponding to one or more dopant diffusion or implantation operations, a process layer corresponding to epitaxial deposition of source and drain regions of transistors, and one or more metallization layers), and there could be different physical defect types at different process layers that could cause the electrical shorts or opens detected as VC defects.

Due to such difficulties, the root cause defect of a VC defect may be misidentified or not found at all.

To address such difficulties, the inspection system of FIG. 1 further advantageously utilizes a layout file 40 which is descriptive of (that is, contains a description of) the layout of the IC undergoing inspection. By way of nonlimiting illustrative example, the layout file 40 may a Graphic Design System (GDS) layout file descriptive of the layout of the IC undergoing inspection, or an Open Artwork System Interchange Standard (OASIS) layout file descriptive of the layout of the IC undergoing inspection, or an electronic Design Interchange Format (EDIF) layout file descriptive of the layout of the IC undergoing inspection, or so forth. While a layout file 40 is referred to, it is contemplated for the layout file 40 to comprise a plurality of layout files, e.g. for different layers of the IC as a nonlimiting illustrative example. A layout image rendering engine 42 renders a layout image 44 of the IC undergoing inspection from the information descriptive of the layout contained in the layout file 40. As will be described later herein, the layout image 44 advantageously provides a common reference for determining a transform between spatial coordinates of the RSEM image 22 of the IC and spatial coordinates of the voltage contrast electron beam image 12, thus enabling fast, automated, and precise mapping of the location of the identified VC defect to the coordinates of the RSEM image 22. Moreover, the layout image 44 advantageously further provides a basis for identifying regions of interest (ROI) for defect analysis by the defect analyzer 24. For example, the layout image 44 identifies locations where a metal gate extrusion or epitaxial damage can be a root cause of an identified VC defect.

The inspection system of FIG. 1 includes the VC-EBI system 10 and the RSEM 20 as described above. The layout file 40 is suitably stored at a database of an illustrative server computer 50 or other information technology (IT) system or storage. In FIG. 1, the defect analyzer 24 is implemented by suitable programming of a computer or other electronic processor 52. More generally, a non-transitory storage medium (not shown, e.g., a hard disk drive, solid state drive, electronic memory, and/or the like) stores instructions readable and executable by the computer or other electronic processor 50 to perform a method of inspecting an IC based on the RSEM image 22 of the IC and the voltage contrast electron beam image 12 of the IC undergoing inspection. The method suitably includes VC defect identification (or, more generally, VC targeted pattern identification) by the VC defect (or, more generally, VC targeted pattern) identifier 14, layout image rendering performed by the rendering engine 42, and defect analysis performed by the defect analyzer 24. It is also noted that the voltage contrast electron beam image 12 of the IC may encompass the entire IC or only a portion of the IC, and likewise the RSEM image 22 may encompass the entire IC or only a portion of the IC (and the portion encompassed by the RSEM image 22 may be different than the portion encompassed by the voltage contrast electron beam image 12), and as previously discussed the RSEM image 22 may also include RSEM images acquired with different imaging parameters (e.g., using electron beams with different accelerating voltages, using different detectors such as the SE detector 30 and the EDX detector 32, and/or so forth). As diagrammatically shown in FIG. 1, the computer or other electronic processor 52 may include or be operatively connected with a display 54 on which a user interface 56 is presented for displaying defect data generated by the inspection system.

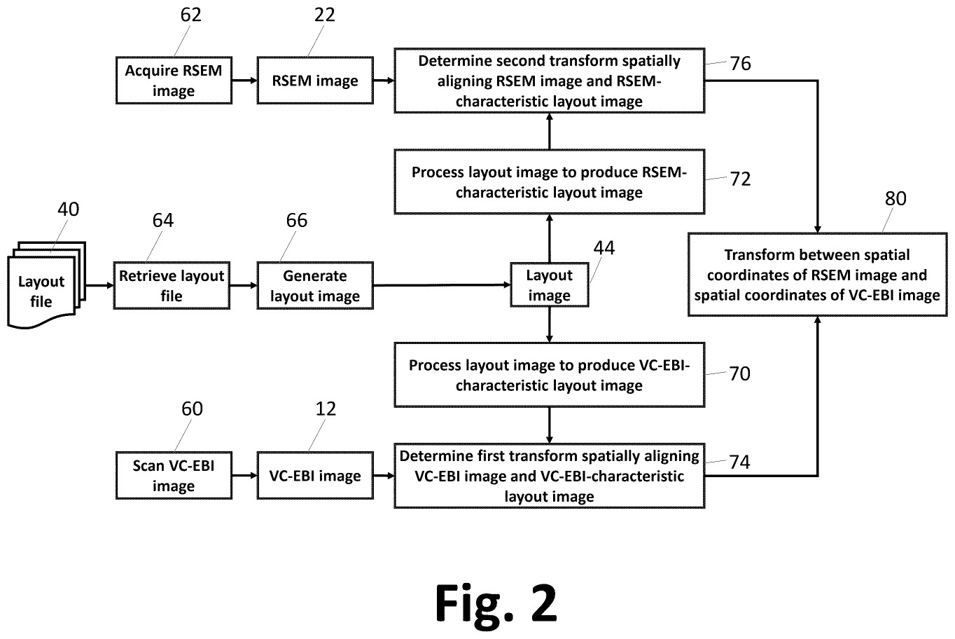

With continuing reference to FIG. 1 and with further reference to FIG. 2, a nonlimiting illustrative embodiment of a method of processing the layout file 40 is shown, which is suitably implemented by the layout rendering engine 42 and the defect analyzer 24. The method of FIG. 2 includes an operation 60 of acquiring the voltage contrast electron beam image 12 using the VC-EBI system 10, and an operation 62 of acquiring the RSEM image 22 using the RSEM 20. As previously noted, the operation 62 in some embodiments is guided by the locations of the VC defects 16 identified in the voltage contrast electron beam image 12 (as indicated by arrow 26 of FIG. 1). An operation 64 retrieves the layout file 40, and an operation 66 performed by the layout rendering engine 42 generated the layout image 44. It is then desired to spatially align the layout image 44 with the voltage contrast electron beam image 12 and RSEM image 22, respectively.

However, the layout image 44 may have substantial dissimilarities from these acquired images 12 and 22. While the layout image 44 has image features corresponding to features of the design-basis layout of the IC undergoing inspection, the voltage contrast electron beam image 12 has image features corresponding to voltage contrast variations across the IC, and the RSEM image 22 has image features corresponding to secondary electron yield variations across the IC. To improve accuracy of the spatial alignment with the voltage contrast electron beam image, in an operation 70 the layout image 44 is processed to produce a VC-EBI-characteristic layout image that more closely matches the contrast of the voltage contrast electron beam image 12. Likewise, in an operation 72 the layout image 44 is processed to produce an RSEM-characteristic layout image that more closely matches the contrast of the RSEM image 22. The operations 70 and 72 can employ various image processing techniques, such as dilation, thinning or other Boolean operations, assignment of dark or bright image pixel intensities to different features in the layout (e.g., to correspond more closely to the bright contrast or dark contrast in the voltage contrast electron beam image 12, or to correspond more closely to grayscale intensity variations in the RSEM image 22), and so forth. The operations 70 and 72 may also include pixel resampling to match the image resolution (i.e., pixel size) of the voltage contrast electron beam image 12 and RSEM image 22, respectively.

In an operation 74, a first spatial transform is determined that spatially aligns the voltage contrast electron beam image 12 of the IC and the VC-EBI-characteristic layout image output by the processing 70. In an operation 76, a second spatial transform is determined that spatially aligns the RSEM image 22 of the IC and the RSEM-characteristic layout image output by the processing 72. A transform 80 between spatial coordinates of the RSEM image 22 of the IC and spatial coordinates of the voltage contrast electron beam image 12 of the IC is then derived from the first spatial transform output by the operation 74 and the second spatial transform output by the operation 76.

By way of a nonlimiting illustrative example, the operation 74 may determine the first transform (T1) by performing rigid or non-rigid spatial alignment of the voltage contrast electron beam image 12 to the VC-EBI-characteristic layout image output by the processing 70. Thus, given coordinate system C_{VC-EBI} of the voltage contrast electron beam image 12 and reference layout image coordinate system C_{Layout} of the layout image 44, the first transform T1 can be represented as:

$$T 1 ( {C}_{V C - E B I} ) = {C}_{Layout} \qquad ( 1 )$$

The operation 76 may determine the second transform (T2) by performing rigid or non-rigid spatial alignment of the RSEM-characteristic layout image output by the processing 72 to the RSEM image 22. Thus, given coordinate system C_{RSEM} of the RSEM image 22 and reference layout image coordinate system C_{Layout} of the layout image 44, the second transform T2 can be represented as:

$$T 2 ( {C}_{L a yout} ) = {C}_{R S E M} \qquad ( 2 )$$

The transform 80 can be the combination of the transforms T1 and T2 (e.g., the transform 80 can be the set of transforms T1 and T2), and/or the transform 80 can be formulated as a combination or composite of the transforms T1 and T2, for example as:

$$T ( {C}_{V C - EBI} , T 1 , T 2 ) = T 2 ( T 1 ( {C}_{V C - EBI} ) ) = {C}_{R S E M} \qquad ( 3 )$$

which is a suitable transform for transforming the location of a VC defect in the voltage contrast electron beam image 12 to the coordinate system of the RSEM image 22. These are merely nonlimiting illustrative examples, and other formulations for the transform 80 can be constructed.

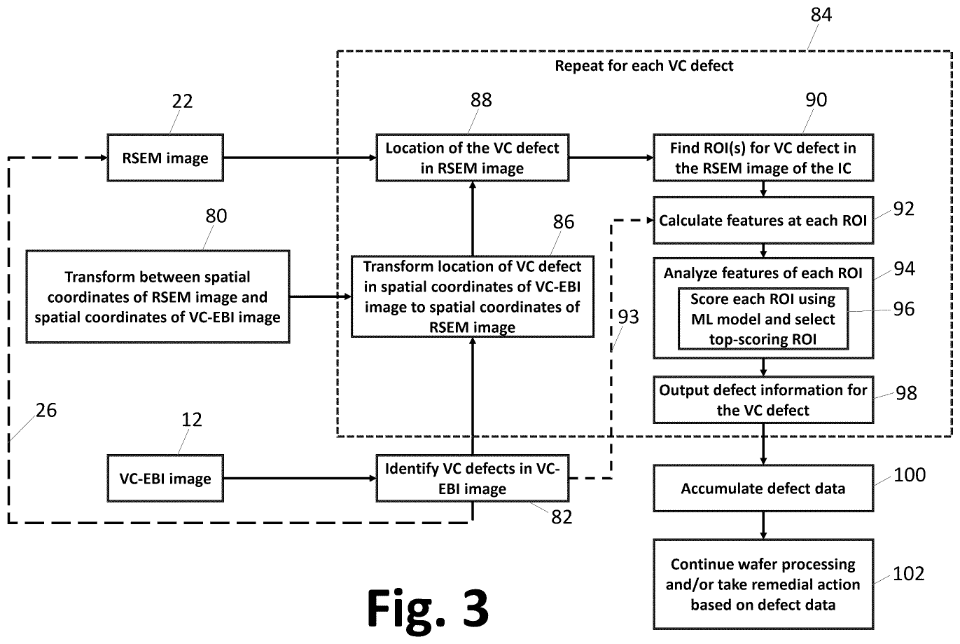

With reference to FIG. 3, a nonlimiting illustrative embodiment of a method of defect analysis suitably implemented by the defect analyzer 24 of FIG. 2 is described. The method of FIG. 3 receives as input the voltage contrast electron beam image 12 which is processed in an operation 82 by the VC defects identifier 14 of FIG. 1 to identify VC defects (or other VC targeted patterns) 16 in the voltage contrast electron beam image 12. The operation 82 identifies VC defects as regions of the voltage contrast electron beam image 12 with substantially higher than average brightness (bright VC defects) or region of the voltage contrast electron beam image 12 with substantially lower than average brightness (dark VC defects). Empirically determined voltage contrast electron beam image intensity thresholds can be used, optionally along with pixel connectivity analysis, to identify the bright and dark VC defects in the voltage contrast electron beam image 12.

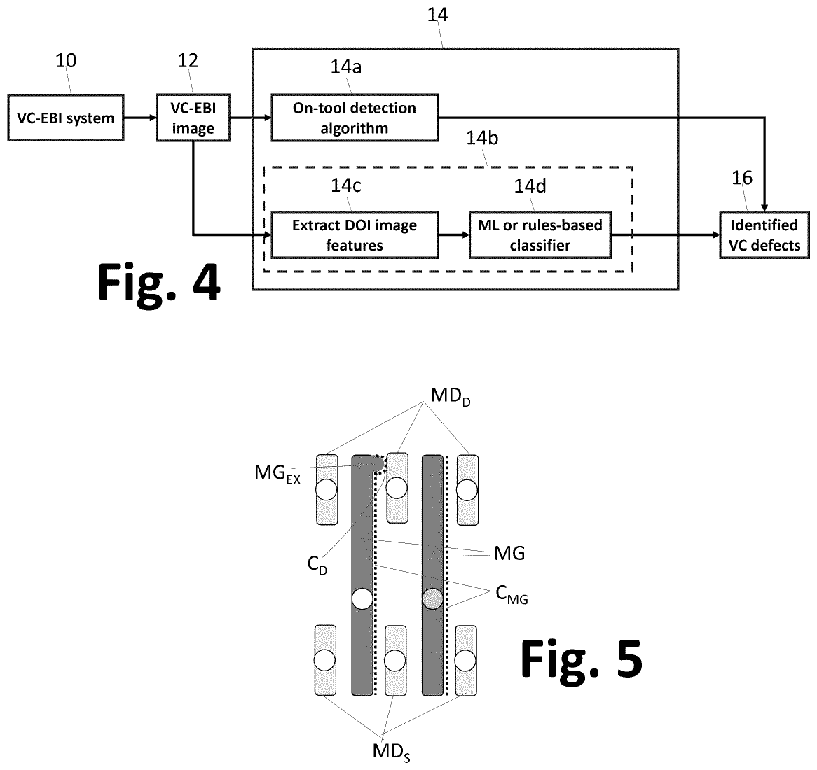

With continuing reference to FIGS. 1 and 3 and with further reference to FIG. 4, in some approaches VC-EBI defect identification 82 is performed by the VC defects identifier 14 using one (or, optionally, more than one) of the general-purpose VC defect detection algorithms 14a that are implemented on the inspection apparatus. However, a general-purpose VC defect (or, more generally, VC targeted pattern) detection algorithm 14a may have limited sensitivity on challenging VC defects such as VC-inducing embedded defects. To improve defect identification, in the nonlimiting illustrative embodiment of FIG. 4, the voltage contrast electron beam images 12 acquired using the VC-EBI system 10 are also processed with a customized VC defect (or, more generally, VC targeted pattern) detection algorithm 14b in a parallel path as shown in FIG. 4. The customized VC defect detection algorithm 14b is constructed to detect VC defects of a target type. The target type of defect for which the customized VC defect detection algorithm 14b is constructed may be a particular defect mechanism (e.g., a gate metallization extrusion, or damage to the epitaxial drain material, or so forth), and/or the target type of defect may be a target type specific to a particular integrated circuit (IC) design (e.g., a circuit feature shape in a particular IC), and/or the target type of defect may be a target type specific to a given fabrication technology, and/or so forth. The customized VC defect detection algorithm 14b can be run, for example, as plug-in executable software on additional central processing units (CPUs) in image computers of the EBI tool, or independently on an off-the-tool image computer or computers connected to the tool via a high-speed electronic data network. In the illustrative example of FIG. 4, the customized VC defect detection algorithm 14b includes an operation 14c which extracts image features that signify the presence of the DOI (defect of interest), then feeds the features to one or more decision rules or ML classifier or classifiers 14d to evaluate the likelihood of detectivity. The identified VC defects 16 include VC defects identified by the general-purpose VC defect detection algorithm 14a and VC defects identified by the VC defect detection algorithm 14b constructed to detect the target type of VC defect.

With reference to FIG. 5, an illustrative example of an implementation of the customized VC defect detection algorithm 14b for VC defect detection is described. FIG. 5 diagrammatically depicts a portion of a voltage contrast electron beam image of a transistor array region which includes a gate metallization MG, drain metallization MD_{D}, and source metallization MDs. The gate metallization MG includes an extrusion MG_{EX}. The customized algorithm 14b performs the DOI image features extraction 14c to determine a boundary or contour CMG of the gate metallization MG by a robust thresholding algorithm that detects the transition from bright MG to dark background; then, the ML or rules-based classification 14d detects the extrusion MG_{EX} as a deviation C_{D} of boundary feature C_{MG} from its expected shape. That is, the classifier 14d analyzes the contour feature(s) C_{MG} and computes or recognizes the boundary extension C_{D} (caused by the MG extrusion MG_{EX}) with respect to a reference MG contour (not shown; i.e. the expected MG contour of a defect-free gate metallization). It will be appreciated that while the illustrative example in FIG. 5 of specialized VC defect detection 14b is directed to detecting an MG extrusion in the illustrative transistor array region, more generally the approach of FIG. 4 can be applied to provide customized VC defect detection for additional and/or other target types of VC defects, such as damage to the epitaxial drain material or so forth. A suitable approach for constructing the customized VC defect detection algorithm 14b for a target type of defect includes acquiring voltage contrast electron beam images of devices with and without defects of the target defect type, determining computationally extractable image features (e.g., image contours such as the illustrative MG boundary features C_{MG}, or image pixel patterns, or so forth) that exhibit significant differentiation with/without defects of the target defect type, and training an ML classifier, or constructing suitable rules, for classifying input image features as either exhibiting a defect of the target defect type, or not exhibiting such a defect. Such construction of the customized VC defect detection algorithm 14b may optionally utilize training voltage contrast electron beam images of devices with and without defects of the target defect type in which the training voltage contrast electron beam images are of instances of a target IC layout, a target IC fabrication technology, and/or so forth to facilitate customization of the customized VC defect detection algorithm 14b to that particular IC layout and/or IC fabrication technology and so forth.

With returning reference to FIG. 3, the method of FIG. 3 further receives as input the RSEM image 22. As previously discussed with reference to FIG. 1, in some embodiments an RSEM image 22 is acquired for each VC defect in the vicinity of that defect, as indicated by the optional flow arrow 26 shown in FIGS. 1 and 3. The method of FIG. 3 also receives the transform 80 between spatial coordinates of the RSEM image 22 and spatial coordinates of the voltage contrast electron beam image 12, determined as previously described with reference to FIG. 2.

As indicated by the dashed box 84 of FIG. 3, each VC defect is analyzed in turn as follows. In an operation 86, the location of the VC defect in the spatial coordinates of the voltage contrast electron beam image 12 is transformed to spatial coordinates of the RSEM image 22 using the transform 80, thereby outputting the location 88 of the VC defect in the RSEM image 22.

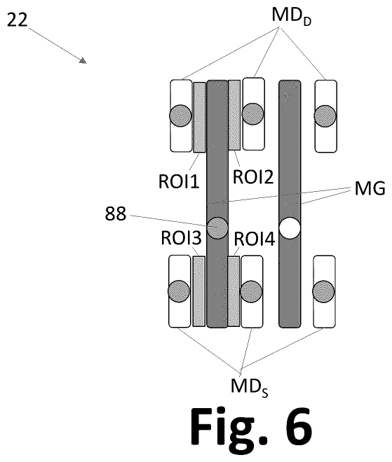

With continuing reference to FIG. 3 and with further reference to FIG. 6, in an operation 90 at least one region of interest (ROI) is identified for the VC under evaluation. Operation 90 utilizes knowledge of the layout of the IC and the mapping between the voltage contrast electron beam image 12 and RSEM image 22 provided by the transform 80. Put another way, the VC defect is identified in the RSEM image 22 using the spatial transform per operation 86, and in the operation 90 each ROI of the plurality of ROIs is found in the RSEM image 22 relative to the location of the VC defect 88 in the RSEM image 22 based on the layout image 44. The ROIs found in the RSEM image 22 relative to a given VC defect are referred to herein as being associated with that VC defect.

To illustrate a nonlimiting example of operation 90, FIG. 6 diagrammatically illustrates a nonlimiting illustrative example of (at least a portion of) an RSEM image 22 depicting a portion of an IC that includes a portion of a transistor array with metal gates MG and drain and source metallization MD_{D} and MD_{S}. (The drain metallization MD_{D} and source metallization MD_{S} are generally formed as a single process layer, with the distinction between source and drain being a consequence of subsequent electrical connectivity provided by electrical traces formed during MEOL and/or BEOL processing). The location 88 of a bright VC defect in the RSEM image 22 is indicated. The bright VC defect is observed in the voltage contrast electron beam image 12, and its corresponding location 88 in the RSEM image 22 is determined by the mapping operation 86 of FIG. 3.

FIG. 6 further illustrates four regions of interest ROI1, ROI2, ROI3, and ROI4 associated with the VC defect 88, which are found in the operation 90 by identifying locations in the RSEM image 22 corresponding to locations in the layout of the IC where a root cause defect could produce the bright VC defect 88 indicated in FIG. 1. The identification of the ROIs in operation 90 utilizes the layout image 44 (or its corresponding RSEM-characteristic layout image produced by processing 72 as previously described with reference to FIG. 2) and a priori knowledge of the electrical connections of the IC (or of the IC-under-fabrication if the IC inspection is performed before completing BEOL processing) and the credible root cause defects that could lead to the observed bright VC defect 88.

For example, with focus on the nonlimiting illustrative example of FIG. 6, the root cause defect producing the bright VC defect 88 could be any of the following: (1) an extrusion of metal of the metal gate MG across region ROI1 causing a short between the adjacent drain metallization MD_{D} and gate MG regions; (2) damage to the epitaxial drain material causing a short across region ROI1 to the neighboring gate MG region; (3) an extrusion of metal of the metal gate MG across region ROI2 causing a short between the adjacent drain metallization MD_{D} and gate MG regions; (4) damage to the epitaxial drain material causing a short across region ROI2 to the neighboring gate MG region; (5) an extrusion of metal of the metal gate MG across region ROI3 causing a short between the adjacent source metallization MDs and gate MG regions; (6) damage to the epitaxial source material causing a short across region ROI3 to the neighboring gate MG region; (6) an extrusion of metal of the metal gate MG across region ROI4 causing a short between the adjacent source metallization MDs and gate MG regions; or (8) damage to the epitaxial source material causing a short across region ROI4 to the neighboring gate MG region.

Since any of these root cause defects could produce the VC defect observed in the voltage contrast electron beam image 12, it is difficult or impossible to determine which root cause defect is responsible for the VC defect by analysis of the voltage contrast electron beam image. Instead, the processing 84 of FIG. 3 analyzes the RSEM image 22 to provide defect information, which in some embodiments is sufficient to isolate the root cause defect. The operation 90 identifies the regions of interest ROI1, ROI2, ROI3, and ROI4 by utilizing the transform 86 (e.g., transform T2 between the layout image 44 and RSEM image 22) to locate the features in the IC layout that are candidates for causing the observed bright VC defect.

It is again noted that FIG. 6 is a nonlimiting illustrative example. In general, the number of ROIs identified in the operation 90 may be one, two, three, four, five, or more. Moreover, the extent of the ROI may differ from that diagrammatically shown in FIG. 6. For example, region ROI1 could encompass part of the neighboring drain metallization MD_{D} and/or part of the neighboring gate metallization MG, and similarly for the other ROIs (i.e., illustrative regions ROI2, ROI3, and ROI4). Still further, while a bright VC defect is described in the example of FIG. 6, an analogous approach is suitably performed in the case of a dark VC defect.

Still further, a given ROI in the layout may have two (or more) corresponding RSEM image ROIs. For example, if the RSEM image 22 includes both a low energy (LE) RSEM acquired using an electron beam with a lower accelerating voltage and a high energy (HE) RSEM image acquired using an electron beam with a higher accelerating voltage, then each ROI of the layout (i.e., each lateral region) could have two RSEM ROIs: a LE RSEM image ROI and a HE RSEM image ROI.

As another nonlimiting illustrative example of an ROI in the layout having two (or more) corresponding RSEM image ROIs, one such RSEM image ROI may be in an RSEM image acquired using a SE detector, and another RSEM image ROI may be in an RSEM comprising an EDX image acquired using an EDX spectrometer.

With returning focus on FIG. 3, in an operation 92 one or more features are calculated for each ROI found in the operation 90. The features can be image features extracted from the respective ROIs of the RSEM image 22 (such as contrast metrics, brightness metrics, texture metrics, image gradient metrics, and/or so forth). In some embodiments, the extracted feature may be the ROI image bitmap itself. The features calculated for each ROI may optionally include one or more RSEM imaging parameters used in the acquiring of the RSEM image of the IC, such as the beam accelerating energy (which is useful as it can indicate the depth-of-penetration and hence is indicative of whether the image contrast is predominantly due to the surface or a buried layer), RSEM image resolution (potentially indicative of whether a small-size defect should be resolved in the RSEM image ROI), and/or so forth.

The operation 92 may also generate features for ROIs based on additional information. For example, if the VC defect being analyzed was detected by the customized VC defect detection algorithm 14b constructed for a target type of defect (see FIGS. 4 and 5), then an additional feature calculated in the operation 92 may be whether the VC defect was detected by the general-purpose VC defect detection algorithms 14a or by the customized VC defect detection algorithm 14b. This is diagrammatically indicated in FIG. 3 by a dashed arrow 93 feeding information from the VC defect identification 82 to the features calculation 92. Thus, the features for the ROI(s) in the RSEM image 22 can include a feature indicating whether the associated VC defect was identified by the defect detection algorithm 14b constructed to detect a target type of VC defect. This additional feature can provide useful information for identifying the root cause of the associated VC defect because it incorporates into the features set information about the defect type obtained from the voltage contrast electron beam image 12 by the VC defects analyzer 14. By way of a nonlimiting illustrative example, referring back to FIG. 5, if the associated VC defect was detected by the defect detection algorithm 14b which was constructed to detect VC defects due to MG extrusions, then a feature indicating the associated VC defect was detected by this defect detection algorithm 14b is information which tends to indicate the ROI may exhibit an MG extrusion.

In an operation 94, the features of each ROI are analyzed. The analysis can employ a formula or analytic analysis, or can employ a machine learning (ML) model to analyze the ROI. In an illustrative example, the operation 94 includes an operation 96 in which each ROI is scored using a ML model and the top-scoring defect is selected as the likely location of the root cause defect. The ML model can, for example, be trained on manually-labeled training ROI images of ICs fabricated with the same layout to distinguish between ROIs with and without a root cause defect. In some implementations, each ROI may be scored using two (or more) ML models. In the example of FIG. 6, by way of illustration, the region ROI1 might be scored using an ML model trained to detect a root cause defect in the form of a gate extrusion and another ML model trained to detect a root cause defect in the form of epitaxial damage to the drain region epitaxy. If a lateral region of interest in the layout has two (or more) corresponding RSEM image ROIs (e.g., a LE RSEM image ROI and a HE RSEM image ROI) then the analysis may process the LE and HE RSEM images separately, or together, or both. In an operation 98, defect information for the VC defect is output.

The ML model used in the analysis 96 can be a random forest classifier, a convolutional neural network (CNN) classifier such as ResNet or YoLo, or another type of artificial neural network (ANN) classifier, or any other suitably trained ML model. In the case of a CNN classifier, the input may in some embodiments comprise the entire ROI image along with optional metadata (e.g., beam acceleration energy). Use of the trained ML model in the operation 96 entails inputting the one or more ROI features derived for the ROI being analyzed to the ML algorithm and in response receiving the score for the ROI from the ML algorithm.

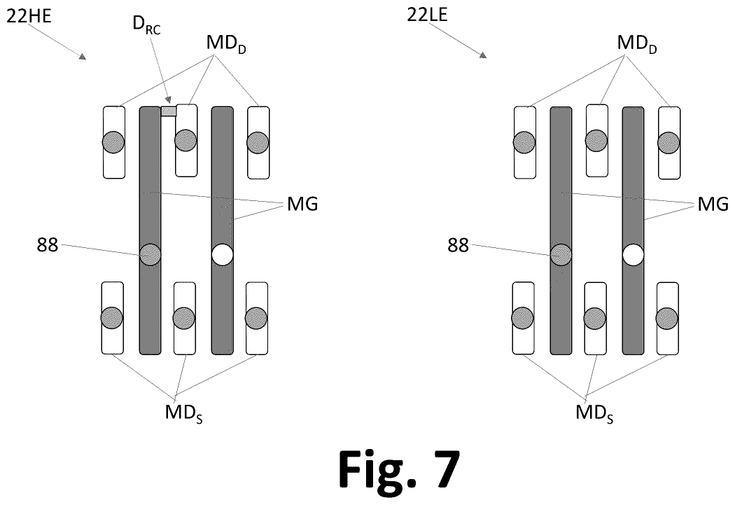

With brief reference to FIG. 7, an illustrative example of the processing 94, 96, 98 of FIG. 3 is described. FIG. 7 shows a high energy (HE) RSEM image 22HE and a low energy (LE) RSEM image 22LE for the same transistor array region shown in FIG. 6, and including the same depicted gate metallization MG, drain metallization MD_{D}, and source metallization MDs. The low energy RSEM image 22LE is acquired using an electron beam with a first accelerating voltage, and the HE RSEM image 22HE is acquired using an electron beam with a second accelerating voltage that is higher than the first accelerating voltage. In general, the electron beam with higher energy used in acquiring the HE RSEM image 22HE probes more deeply into the IC than the electron beam with lower energy used in acquiring the LE RSEM image 22LE. Hence, the HE RSEM image 22HE has image contrast corresponding to a buried layer (or layers) of the IC; whereas, the LE RSEM image 22LE has image contrast corresponding to a surface or less deeply buried layer (or layers) of the IC. In the instant example, the source and drain epitaxy are formed first, and hence are a deeper layer than the subsequent gate metallization MG. In the illustrative example of FIG. 7, it is assumed that the root cause defect is epitaxial damage of the drain epitaxy neighboring (or included in) region ROI1 (as indicated in FIG. 6). This epitaxial damage produces strong image contrast DRC visible in the HE RSEM image 22HE (due to the higher accelerating energy of the electron beam penetrating significantly to the buried epitaxy layer); whereas, the epitaxial damage produces weak or nonexistent contrast in the LE RSEM image 22LE (due to the lower accelerating energy of the electron beam not penetrating significantly to the buried epitaxy layer). Consequently, analysis (and/or comparison) of region ROI1 in the HE RSEM image 22HE compared with region ROI1 in the LE RSEM image 22LE provides a basis for distinguishing both that the root cause defect is in the lateral location of region ROI1 and whether the root cause defect is in the epitaxy layer or the metallization layer.

While FIG. 7 diagrammatically shows an example in which the defect is in the buried (e.g., epitaxy) layer and is detected by analysis of the HE RSEM image 22HE, it will be appreciated that in the case of a surface defect (or less deeply buried defect), the analysis of the LE RSEM image 22LE may be effective for detecting the defect. For instance, if the defect is an extrusion of the gate metal MG this may exhibit strong contrast in the LE RSEM image 22LE and low (or nonexistent) contrast in the HE RSEM image 22HE. Moreover, while FIG. 7 depicts an example in which two RSEM images 22 are acquired and analyzed which have two different accelerating beam energies, this could be extended to RSEM images acquired and analyzed which have three (or more) different accelerating beam energies to provide further depth profiling to isolate root cause defects by different depths.

As previously noted, the operations denoted by the dashed box 84 of FIG. 3 are performed for each VC defect identified in the operation 82. In an operation 100 the defect data produced by running the operations 84 for each VC defect are accumulated (e.g., stored in an array or other suitable data structure). In an optional operation 102, the accumulated defect data are analyzed to determine whether to continue wafer processing (if the defect data indicates the number of defects is sufficiently low and/or the defect types are acceptable), or whether the wafer should be scrapped (in which case it may be further analyzed, and/or the semiconductor processing workflow reviewed, to ascertain why the semiconductor wafer has an unacceptable number/types of defects). Thus, the operation 100 entails accumulating defect information by repeating the operation 82 identifying the VC defect in the voltage contrast electron beam image 12 of the IC, the operations 86 and 90 of the locating of at least one ROI in the RSEM image associated with the VC defect, and the operations 92, 94, and 98 of analyzing of the at least one ROI in the RSEM image of the IC for a plurality of VC defects. The operation 102 in some embodiments entails determining the IC passes inspection based on the accumulated defect information, and in response to the determination that the IC passes inspection, performing additional semiconductor fabrication processing of the IC (e.g., completing BEOL processing and optional packaging of the IC in a nonlimiting example).

The processing of FIGS. 2 and 3 may be performed by the computer or other electronic processor 52 of FIG. 1, or by the server computer 50, or by a combination of these systems 50 and 52 (e.g., with computationally complex processing such as implementation of the ML model(s) of operation 96 being performed by the server computer 50 and less computationally complex processing such as applying the transform 86 being performed by the computer or other electronic processor 52. These are merely nonlimiting illustrative examples of some suitable processing hardware configurations.

In the following, some further embodiments are described.

In a nonlimiting illustrative embodiment, a method is disclosed of analyzing an integrated circuit (IC). The method includes acquiring a review scanning electron microscope (RSEM) image of the IC, acquiring a voltage contrast electron beam image of the IC, rendering a layout image from a layout file descriptive of a layout of the IC, determining a transform between spatial coordinates of the RSEM image of the IC and spatial coordinates of the voltage contrast electron beam image of the IC using the layout image, identifying a voltage contrast (VC) targeted pattern in the voltage contrast electron beam image of the IC, locating at least one region of interest (ROI) in the RSEM image of the IC associated with the VC targeted pattern using the spatial transform, and analyzing the at least one ROI in the RSEM image of the IC to produce defect information for the VC targeted pattern.

In a nonlimiting illustrative embodiment, a non-transitory storage medium stores instructions readable and executable by an electronic processor to perform a method of analyzing an IC based on an RSEM image of the IC and a voltage contrast electron beam image of the IC. The method includes determining a transform between spatial coordinates of the RSEM image of the IC and spatial coordinates of the voltage contrast electron beam image of the IC using a layout image depicting a design-basis layout of the IC, identifying VC defects in the voltage contrast electron beam image of the IC, locating regions of interest (ROIs) in the RSEM image of the IC associated with VC defects using the spatial transform, and analyzing the ROIs in the RSEM image of the IC to determine root causes of the VC defects.

In a nonlimiting illustrative embodiment, an apparatus for analyzing an IC is disclosed. The apparatus includes a scanning electron microscope configured to acquire an RSEM image of an associated IC, a voltage contrast electron beam microscope configured to acquire a voltage contrast electron beam image of the associated IC, and an electronic processor. The electronic processor is programmed to perform a method including: determining a transform between spatial coordinates of the RSEM image of the IC and spatial coordinates of the voltage contrast electron beam image of the IC using a layout image depicting a design-basis layout of the IC; identifying voltage contrast (VC) targeted patterns in the voltage contrast electron beam image of the IC; locating ROIs in the RSEM image of the IC associated with the VC targeted patterns using the layout image; and analyzing the ROIs in the RSEM image of the IC associated with each VC targeted pattern to produce information for the VC targeted pattern.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of analyzing an integrated circuit (IC), the method comprising:
acquiring a review scanning electron microscope (RSEM) image of the IC;
acquiring a voltage contrast electron beam image of the IC;
rendering a layout image from a layout file descriptive of a layout of the IC;
determining a transform between spatial coordinates of the RSEM image of the IC and spatial coordinates of the voltage contrast electron beam image of the IC using the layout image;
identifying a voltage contrast (VC) targeted pattern in the voltage contrast electron beam image of the IC;
locating at least one region of interest (ROI) in the RSEM image of the IC associated with the VC targeted pattern using the spatial transform; and
analyzing the at least one ROI in the RSEM image of the IC to produce defect information for the VC targeted pattern.

2. The method of claim 1, wherein the determining of the transform includes:
processing the layout image to produce an RSEM-characteristic layout image;
processing the layout image to produce a voltage contrast electron beam image-characteristic layout image;
determining a first spatial transform that spatially aligns the voltage contrast electron beam image and the voltage contrast electron beam image-characteristic layout image; and
determining a second spatial transform that spatially aligns the RSEM image of the IC and the RSEM-characteristic layout image;
wherein the transform between spatial coordinates of the RSEM image of the IC and spatial coordinates of the voltage contrast electron beam image of the IC is derived from the first spatial transform and the second spatial transform.

3. The method of claim 1, wherein the analyzing includes:
deriving features for the at least one ROI in the RSEM image; and
analyzing the features derived for the at least one ROI to produce the defect information for the VC targeted pattern.

4. The method of claim 3, wherein the at least one ROI in the RSEM image comprises a plurality of ROIs in the RSEM image, the deriving of features includes deriving one or more ROI features for each ROI of the plurality of ROIs, and the analyzing includes:
scoring each ROI by analyzing the one or more ROI features derived for that ROI; and
producing the defect information for the VC targeted pattern based on a top-scoring ROI of the plurality of ROIs and/or based on ROI features of the top-scoring ROI.

5. The method of claim 4, wherein:
the RSEM image includes a low energy RSEM image acquired using an electron beam with a first accelerating voltage and a high energy RSEM image acquired using an electron beam with a second accelerating voltage that is higher than the first accelerating voltage, and
the defect information includes layer information for a root cause defect corresponding to the VC targeted pattern determined based on whether the top-scoring ROI of the plurality of ROIs is in the low energy RSEM image or in the high energy RSEM image.

6. The method of claim 4, wherein the locating of the plurality of ROIs in the RSEM image of the IC associated with the VC targeted pattern using the spatial transform includes:
locating the VC targeted pattern in the RSEM image using the spatial transform; and
locating each ROI of the plurality of ROIs in the RSEM image relative to the location of the VC targeted pattern in the RSEM image based on the layout image.

7. The method of claim 3, wherein:
the identification of the VC targeted pattern in the voltage contrast electron beam image of the IC includes applying a VC targeted pattern detection algorithm constructed to detect a target type of VC targeted pattern; and
the deriving of the features for the at least one ROI in the RSEM image includes deriving a feature indicating whether the associated VC targeted pattern was identified by the defect detection algorithm constructed to detect the target type of VC targeted pattern.

8. The method of claim 1, where the identification of the VC targeted pattern in the voltage contrast electron beam image of the IC includes:
applying a general-purpose VC targeted pattern detection algorithm to the voltage contrast electron beam image; and
applying a VC targeted pattern detection algorithm constructed to detect a target type of VC targeted pattern;
wherein the identified VC targeted pattern includes VC targeted patterns identified by the general-purpose VC targeted pattern detection algorithm and VC targeted patterns identified by the VC targeted pattern detection algorithm constructed to detect the target type of VC targeted pattern.

9. The method of claim 8, where the target type of VC targeted pattern is a gate metallization extrusion, and the VC targeted pattern detection algorithm constructed to detect the gate metallization extrusion performs contour extraction to detect a contour of the gate metallization and applying a classifier to the contour of the gate metallization to detect a VC targeted pattern caused by a gate metallization extrusion.

10. The method of claim 1, wherein the RSEM image comprises a plurality of RSEM images including:
an RSEM image acquired using a secondary electron detector; and
an RSEM image comprising an energy-dispersive X-ray (EDX) image acquired using an EDX spectrometer.

11. A non-transitory storage medium storing instructions readable and executable by an electronic processor to perform a method of analyzing an integrated circuit (IC) based on a review scanning electron microscope (RSEM) image of the IC and a voltage contrast electron beam image of the IC, the method comprising:
determining a transform between spatial coordinates of the RSEM image of the IC and spatial coordinates of the voltage contrast electron beam image of the IC using a layout image depicting a design-basis layout of the IC;
identifying voltage contrast (VC) defects in the voltage contrast electron beam image of the IC;
locating regions of interest (ROIs) in the RSEM image of the IC associated with respective VC defects using the spatial transform; and
analyzing the ROIs in the RSEM image of the IC to determine root causes of the VC defects.

12. The non-transitory storage medium of claim 11, wherein the determining of the transform includes:
determining a first spatial transform that spatially aligns the voltage contrast electron beam image and the layout image; and
determining a second spatial transform that spatially aligns the RSEM image of the IC and the layout image;
wherein the transform between spatial coordinates of the RSEM image of the IC and spatial coordinates of the voltage contrast electron beam image of the IC is derived from the first spatial transform and the second spatial transform.

13. The non-transitory storage medium of claim 11, wherein the analyzing includes:
deriving one or more ROI features for each ROI in the RSEM image associated with a VC defect under analysis;
scoring each ROI associated with the VC defect under analysis by analyzing the one or more ROI features derived for that ROI;
identifying a top-scoring ROI associated with the VC defect under analysis based on the scoring; and
determining the root cause of the VC defect under analysis based at least in part on the identification of the top-scoring ROI.

14. The non-transitory storage medium of claim 13, wherein:
the RSEM image includes a low energy RSEM image acquired using an electron beam with a first accelerating voltage and a high energy RSEM image acquired using an electron beam with a second accelerating voltage that is higher than the first accelerating voltage, and
the root cause of the VC defect under analysis is determined at least in part based on whether the top-scoring ROI is in the low energy RSEM image or in the high energy RSEM image.

15. The non-transitory storage medium of claim 13, wherein the scoring of each ROI associated with the VC defect under analysis comprises inputting the one or more ROI features derived for that ROI to a machine learning (ML) algorithm and in response receiving the score for the ROI from the ML algorithm.

16. The non-transitory storage medium of claim 11, wherein the locating of the ROIs in the RSEM image of the IC using the spatial transform includes, for each VC defect:
locating the VC defect in the RSEM image using the spatial transform; and
locating each ROI in the RSEM image relative to the location of the VC defect in the RSEM image based on the layout image.

17. An apparatus for analyzing an integrated circuit (IC), the inspection apparatus comprising:
a scanning electron microscope configured to acquire a review scanning electron microscope (RSEM) image of an associated IC;
a voltage contrast electron beam microscope configured to acquire a voltage contrast electron beam image of the associated IC; and
an electronic processor programmed to perform a method including:
determining a transform between spatial coordinates of the RSEM image of the IC and spatial coordinates of the voltage contrast electron beam image of the IC using a layout image depicting a design-basis layout of the IC;
identifying voltage contrast (VC) targeted patterns in the voltage contrast electron beam image of the IC;
locating regions of interest (ROIs) in the RSEM image of the IC associated with the VC targeted patterns using the layout image; and
analyzing the ROIs in the RSEM image of the IC associated with each VC targeted pattern to produce information for the VC targeted pattern.

18. The inspection apparatus of claim 17, wherein the analyzing of the ROIs in the RSEM image of the IC associated with each VC targeted pattern to produce information for the VC targeted pattern includes:
deriving one or more ROI features for each ROI in the RSEM image associated with the VC targeted pattern;
scoring each ROI associated with the VC targeted pattern by analyzing the one or more ROI features derived for that ROI; and
identifying a top-scoring ROI.

19. The inspection apparatus of claim 18, wherein the scoring of each ROI associated with the VC targeted pattern comprises inputting the one or more ROI features derived for that ROI to a machine learning (ML) algorithm and in response receiving the score for the ROI from the ML algorithm.

20. The inspection apparatus of claim 18, wherein:
the ROIs associated with the VC targeted pattern correspond to locations in the RSEM image of the IC relative to the location of the VC targeted pattern in the RSEM image of the IC, and
the information for the VC targeted pattern includes a root cause of the VC targeted pattern determined at least in part based on the top-scoring ROI.
